(19) United States
(12) Patent Application Publication
(10) Pub. No.: US 2005/0199965 A1
(43) Pub. Date: Sep. 15, 2005

(54) Semiconductor device and method for manufacturing semiconductor device

(76) Inventors: Juri Kato, Nagano (JP); Teruo Takizawa, Nagano (JP)

Correspondence Address: HARNESS, DICKEY & PIERCE, P.L.C., P.O. BOX 828, BLOOMFIELD HILLS, MI, 48303, US

(21) Appl. No.: 11/079,258

(22) Filed: Mar. 14, 2005

(30) Foreign Application Priority Data
Mar. 15, 2004 (JP) 2004-072516

(51) Int. Cl. H01L 29/76; H01L 21/8238

(52) U.S. Cl. 257/369; 438/199

(57) ABSTRACT

A semiconductor device comprising: a semiconductor layer formed on a dielectric; a gate electrode formed on the semiconductor layer; a compound metal layer disposed on a source side in a manner to contact a body region of the semiconductor layer; and an impurity diffusion layer disposed on a drain side in a manner to contact the body region of the semiconductor layer.

### RELATED APPLICATIONS

This application claims priority to Japanese Patent Application No. 2004-072516 filed Mar. 15, 2004 which is hereby expressly incorporated by reference herein in its entirety.

### BACKGROUND

1. Technical Field

The present invention relates to semiconductor devices and methods for manufacturing semiconductor devices, and in particular, may be preferentially applied to field effect transistors that are formed on a SOI (Silicon On Insulator) substrate.

2. Related Art

In a MOSFET (Metal Oxide Semiconductor Field Effect Transistor) having a conventional SOI structure, such as the one described in Japanese Laid-open patent application 2003-158091, a silicide film having a high resistance crystal structure C49 is transferred to a silicide film having a low resistance crystal structure C54, to thereby form, on a silicon single crystal layer, a silicide layer whose film thickness is small and thin-line effect is suppressed.

Also, for example, Japanese Laid-open patent application HEI 7-211917 describes a method to realize a higher drain breakdown voltage with a shorter offset gate region, by providing an offset gate region with a plurality of regions having impurity concentrations formed in stages such that the impurity concentration on the drain region side is higher than the impurity concentration on the channel region side.

However, in the conventional MOSFET, a source and a drain have the same structures that are arranged symmetrically, as described in Japanese Laid-open patent application 2003-158091. For this reason, if a part of holes generated by impact ionization in a high electric filed region adjacent to the drain is accumulated in the body region, the body potential positively rises, and electrons are injected from the source that plays a role of an emitter to the body region that plays a role of a base. As a result, there is a problem in the conventional MOSFET in that a bipolar operation with the body region being a base takes place, such that the breakdown voltage between the source and drain lowers, and high-voltage operations at several V to several tens V cannot be conducted.

Also, according to the method described in Japanese Laid-open patent application HEI 7-211917, the lower concentration section (offset gate region) of the drain region needs to be made longer in order to improve the drain breakdown voltage. As a result, there is a problem in that the resistance of the offset gate region increases, and the current to turn on the MOSFET is suppressed, which would prevent ICs from attaining higher speeds and lower power consumption.

Accordingly, it is an object of the present invention to provide a semiconductor device that can suppress lowering of an on-current of a field effect transistor whose body region is disposed on a dielectric

### SUMMARY

To solve the problems described above, a semiconductor device in accordance with an embodiment of the present invention is characterized in comprising: a semiconductor layer formed on a dielectric; a gate electrode formed on the semiconductor layer; a compound metal layer disposed on a source side in a manner to contact a body region of the semiconductor layer; and an impurity diffusion layer disposed on a drain side in a manner to contact the body region of the semiconductor layer.

According to the above, the impurity concentration on the drain side can be controlled, and the electric field concentration at an edge of the drain of the body region can be alleviated, such that the drain breakdown voltage can be improved.

On the other hand, holes accumulated in the body region can be pulled out through a Schottky junction formed between the compound metal layer and the semiconductor layer, such that the body potential can be prevented from rising positively. As a result, injection of electrons from the source to the body region can be suppressed, and a bipolar operation with the body region acting as a base can be avoided while an increase in the resistance of the drain side can be suppressed. As a result, while suppressing lowering of on-current, decreasing of breakdown voltage between the source and drain can be suppressed, such that high-voltage operations at about several V-several tens V can be accommodated, and higher operation speeds and lower power consumption of ICs can be achieved.

Also, the semiconductor device in accordance with an embodiment of the present invention is characterized in comprising: a side wall formed on a source side with respect to the gate electrode; and a high concentration impurity diffusion layer that is disposed in a manner to contact the body region of the semiconductor layer and the compound metal layer under the side wall.

As a result, while holes accumulated in the body region can be pulled out through the compound metal layer, a source end region where carriers travel can be formed from a pn junction. Accordingly, in a sub-threshold region, a drain current can be decided by carriers that thermally surpass the sum of a built-in potential of the pn junction and a channel surface potential (a potential barrier at the surface of the source end region), such that a bipolar operation of a field effect transistor can be avoided, and a steep rising characteristic (good Swing value) can be achieved.

Also, the high concentration impurity diffusion layer can be formed in a self-alignment manner with respect to the gate electrode, such that a barrier among the source, channel inversion layer and drain where carriers travel can be eliminated under a gate voltage that is larger than a threshold value at which a channel is formed. For this reason, the on-resistance can be lowered, and a high on-current and a high on/off ratio can be realized, such that higher operation speeds and lower power consumption of ICs can be achieved.

Also, the semiconductor device in accordance with an embodiment of the present invention is characterized in that the compound metal layer is separated from the dielectric, and the high concentration impurity diffusion layer has a depth that is shallower than a thickness of the compound metal layer.

Accordingly, the semiconductor layer can be disposed under the compound metal layer, variations in the Schottky barrier and specific resistance can be reduced, and the heat-resisting property can be improved.

Also, a semiconductor device in accordance with an embodiment of the present invention is characterized in comprising: a semiconductor layer formed on a dielectric; a gate electrode formed on the semiconductor layer; a side wall formed on a source side with respect to the gate electrode; a first intermetallic compound layer disposed on a source side in a manner to contact a body region of the semiconductor layer and separated from the gate electrode by a width of the side wall; a first impurity diffusion layer that is formed in the semiconductor layer under the side wall and shallower than a thickness of the first intermetallic compound layer; a second impurity diffusion layer disposed on the drain side in a manner to contact the body region of the semiconductor layer and the dielectric; and a second intermetallic compound layer formed inside the second impurity diffusion layer.

Accordingly, between the source and the body region, a pn junction disposed at a channel surface and a Schottky junction formed between the first intermetallic compound layer and the semiconductor layer can be connected in parallel, and the first impurity diffusion layer can be formed in a self-alignment manner with respect to the gate electrode. For this reason, holes accumulated in the body region can be pulled out through the first intermetallic compound layer, and a barrier among the source, channel inversion layer and drain where carriers travel can be eliminated under a gate voltage that is larger than a threshold value at which a channel is formed. As a result, a bipolar operation with the body region acting as a base can be avoided while the on-resistance can be lowered, lowering of breakdown voltage between the source and drain can be suppressed, high-voltage operations at about several V-several tens V can be accommodated, and higher operation speeds and lower power consumption of ICs can be achieved.

Also, the semiconductor device in accordance with an embodiment of the present invention is characterized in that the first intermetallic compound layer and the second intermetallic compound layer are separated from the dielectric.

Accordingly, the semiconductor layer can be disposed under the first intermetallic compound layer and the second intermetallic compound layer, variations in the Schottky barrier and specific resistance can be reduced, and the heat-resisting property can be improved.

Furthermore, the semiconductor device in accordance with an embodiment of the present invention is characterized in that the second impurity diffusion layer has a plurality of regions with impurity concentrations gradually increasing from the gate electrode side to the drain side.

Accordingly, an increase in the drain resistance can be suppressed, the impurity concentration at a drain edge section of the body region can be lowered, and an electric field concentration at the drain edge section of the body region can be alleviated, such that the drain breakdown voltage can be improved.

Also, a method for manufacturing a semiconductor device in accordance with an embodiment of the present invention is characterized in comprising the steps of: forming a gate dielectric film on a semiconductor layer formed on a dielectric; forming a gate electrode on the gate dielectric film; forming a first resist pattern that covers the semiconductor layer on a drain side with respect to the gate electrode and exposes the semiconductor layer on a source side; forming a high concentration impurity diffusion layer having a depth shallower than a film thickness of the semiconductor layer on the source side by conducting an ion injection using the gate electrode and the first resist pattern as a mask; forming a second resist pattern that covers the semiconductor layer on the source side with respect to the gate electrode, and exposes the semiconductor layer on the drain side; forming an impurity diffusion layer having a depth that is set to reach the dielectric on the drain side by conducting an ion injection using the gate electrode and the second resist pattern as a mask; depositing a dielectric film on the semiconductor layer having the impurity diffusion layer formed thereon; conducting an anisotropic etching of the dielectric film to expose a part of the high concentration impurity diffusion layer and form a side wall disposed on the source side with respect to the gate electrode; forming a metal layer on the semiconductor layer where the part of the high concentration impurity diffusion layer is exposed; reacting the metal layer and the semiconductor layer to form a compound metal layer on the source side, having a film thickness greater than a depth of the high concentration impurity diffusion layer and separated from the dielectric; and removing an unreacted portion of the metal layer.

Accordingly, on the source side, the semiconductor layer can be disposed below the compound metal layer, and the high concentration impurity diffusion layer and the compound metal layer can be formed in a self-alignment manner, both of which are disposed in a manner to contact the body region. On the drain side, the impurity diffusion layer having an optimized impurity concentration can be formed. Consequently, variations in the Schottky barrier and specific resistance of the compound metal layer can be reduced, holes accumulated in the body region can be pulled out through the compound metal layer, and a barrier among the source, channel inversion layer and drain where carriers travel can be eliminated under a gate voltage that is greater than a threshold value at which a channel is formed. As a result, a bipolar operation with the body region acting as a base can be avoided while the on-resistance can be lowered, such that field effect transistors capable of achieving higher operation speeds and lower power consumption of ICs can be stably manufactured.

Furthermore, a method for manufacturing a semiconductor device in accordance with an embodiment of the present invention is characterized in comprising the steps of: forming a gate dielectric film on a semiconductor layer formed on a dielectric; forming a gate electrode on the gate dielectric film; forming a first resist pattern that covers the semiconductor layer on a drain side with respect to the gate electrode and exposes the semiconductor layer on a source side; forming a high concentration impurity diffusion layer having a depth shallower than a film thickness of the semiconductor layer on the source side by conducting an ion injection using the gate electrode and the first resist pattern as a mask; forming a second resist pattern that covers the semiconductor layer on the source side with respect to the gate electrode, and exposes the semiconductor layer on the drain side; forming a first impurity diffusion layer having a depth that is set to reach the dielectric on the drain side by conducting an ion injection using the gate electrode and the second resist pattern as a mask; forming a third resist pattern that covers the semiconductor layer on the source side with respect to the gate electrode, and exposes an area among the first impurity diffusion layer close to the drain; forming a second impurity diffusion layer having an impurity concentration higher than the first impurity diffusion layer and closer to the drain than the first impurity diffusion layer by conducting an ion injection using the gate electrode and the third resist pattern as a mask; depositing a dielectric film on the semiconductor layer having the second impurity diffusion layer formed thereon; forming a fourth resist pattern on the dielectric film disposed in a manner to expose the source side with respect to the gate electrode, and cover the first impurity diffusion layer; conducting an anisotropic etching of the dielectric film using the fourth resist pattern as a mask, to form a side wall that is disposed on the source side with respect to the gate electrode and exposes a part of the high concentration impurity diffusion layer, and to form an opening section in the dielectric film which is disposed on the drain side with respect to the gate electrode and exposes the second impurity diffusion layer; forming a metal layer on the semiconductor layer where the part of the high concentration impurity diffusion layer and the second impurity diffusion layer are exposed; reacting the metal layer and the semiconductor layer to form a first intermetallic compound layer on the source side, having a film thickness greater than a depth of the high concentration impurity diffusion layer and separated from the dielectric, and a second intermetallic compound layer on the drain side disposed inside the second impurity diffusion layer; and removing an unreacted portion of the metal layer.

Accordingly, on the source side, the semiconductor layer can be disposed below the compound metal layer, and the high concentration impurity diffusion layer and the compound metal layer can be formed in a self-alignment manner, both of which are disposed in a manner to contact the body region. On the drain side, an increase in the drain resistance can be suppressed, and the impurity concentration at a drain edge section of the body region can be lowered. Consequently, while variations in the Schottky barrier and specific resistance of the compound metal layer can be reduced, holes accumulated in the body region can be pulled out through the compound metal layer. Also, a barrier among the source, channel inversion layer and drain where carriers travel can be eliminated under a gate voltage that is greater than a threshold value at which a channel is formed, and the electric field concentration at a drain end section of the body region can be alleviated. As a result, while a bipolar operation with the body region acting as a base can be avoided, lowering of the on-current can be suppressed, such that field effect transistors having a high drain breakdown voltage, and capable of achieving higher operation speeds and lower power consumption of ICs can be stably manufactured.

### BRIEF DESCRIPTION OF THE DRAWINGS

FIG. 1 is a cross-sectional view indicating a schematic structure of a semiconductor device in accordance with an embodiment of the present invention.

FIGS. 2(a)-(d) are cross-sectional views indicating a method for manufacturing a semiconductor device in accordance with an embodiment of the present.

FIGS. 3(a)-(d) are cross-sectional views indicating a method for manufacturing a semiconductor device in accordance with an embodiment of the present.

### DETAILED DESCRIPTION

A semiconductor device and its manufacturing method in accordance with embodiments of the present invention are described below with reference to the accompanying drawings.

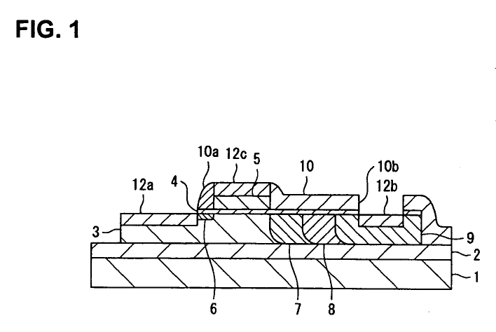

FIG. 1 is a cross-sectional view schematically indicating the structure of a semiconductor device in accordance with an embodiment of the present invention.

In FIG. 1, a dielectric layer 2 is formed on a semiconductor substrate 1, and a single crystal semiconductor layer 3 is formed on the dielectric layer 2. For example, Si, Ge, SiGe, SiC, SiSn, PbS, GaAs, InP, GaP, GaN, ZnSe, and the like can be used as a material of the semiconductor substrate 1 and the single crystal semiconductor layer 3. For example, SiO₂, SiON or Si₃N₄ can be used as the dielectric layer 2. Also, for example, a SOI substrate can be used as the semiconductor substrate 1 with which the single crystal semiconductor layer 3 is formed on the dielectric layer 2. As the SOI substrate, a SIMOX (Separation by Implanted Oxygen) substrate, a laminated substrate, a laser annealed substrate, or the like can be used. Moreover, an insulating substrate consisting of sapphire, glass, ceramic or the like can be used instead of the semiconductor substrate 1 with which the dielectric layer 2 is formed. Moreover, a polycrystal semiconductor layer or an amorphous semiconductor layer can be used instead of the single crystal semiconductor layer 3.

A gate electrode 5 is formed over the single crystal semiconductor layer 3 through a gate dielectric film 4, and a side wall spacer 10a is formed on the source side with respect to the gate electrode 5. In the single crystal semiconductor layer 3 on the source side, a high impurity concentration diffusion layer 6 disposed below the side wall spacer 10a is formed, and a compound metal layer 12a that is separated by the width of the side wall spacer 10a from the gate electrode 5 is formed. It is noted here that the high concentration impurity diffusion layer 6 is disposed in the single crystal semiconductor layer 3 in a manner to be separated from the dielectric layer 2, and the compound metal layer 12a can be directly contacted with a body region of the single crystal semiconductor layer 3. Also, the compound metal layer 12a is disposed in the single crystal semiconductor layer 3 in a manner to be separated from the dielectric layer 2, and the depth of the high concentration impurity diffusion layer 6 can be made shallower than the thickness of the compound metal layer 12a.

The compound metal layer 12a can be formed by reacting metal and semiconductor. For example, when the single crystal semiconductor layer 3 consists of Si, the compound metal layer 12a can consist of silicide. Also, the compound metal layer 12a can form a Schottky junction with the single crystal semiconductor layer 3. Moreover, when the single crystal semiconductor layer 3 is an n-type or intrinsic semiconductor layer, the high concentration impurity diffusion layer 6 can be a p-type layer. When the single crystal semiconductor layer 3 is a p-type or intrinsic semiconductor layer, the high concentration impurity diffusion layer 6 can be an n-type layer.

On the other hand, an interlayer dielectric film 10 is formed on the drain side with respect to the gate electrode 5. A low concentration impurity diffusion layer 7 is formed on the drain side in the single crystal semiconductor layer 3. An intermediate concentration impurity diffusion layer 8 having an impurity concentration greater than that of the lower concentration impurity diffusion layer 7 is formed closer to the drain than the lower concentration impurity diffusion layer 7. A high concentration impurity diffusion layer 9 having an impurity concentration greater than that of the intermediate concentration impurity diffusion layer 8 is formed closer to the drain than the intermediate concentration impurity diffusion layer 8. Bottom surfaces of the lower concentration impurity diffusion layer 7, the intermediate concentration impurity diffusion layer 8, and the high concentration impurity diffusion layer 9 can contact the dielectric layer 2, and the low concentration impurity diffusion layer 7 can contact the body region of the single crystal semiconductor layer 3. When the single crystal semiconductor layer 3 is an n-type or intrinsic semiconductor layer, the lower concentration impurity diffusion layer 7, the intermediate concentration impurity diffusion layer 8, and the high concentration impurity diffusion layer 9 can be p-type. When the single crystal semiconductor layer 3 is a p-type or intrinsic semiconductor layer, the lower concentration impurity diffusion layer 7, the intermediate concentration impurity diffusion layer 8, and the high concentration impurity diffusion layer 9 can be n-type.

An opening section 10b that exposes the surface of the high concentration impurity diffusion layer 9 is formed in the interlayer dielectric film 10, and a compound metal layer 12b is formed on the high concentration impurity diffusion layer 9 that is exposed through the opening section 10b. Also, a compound metal layer 12c is formed on the gate electrode 5.

It is noted here that, by arranging the high concentration impurity diffusion layer 6 below the side wall spacer 10a, and contacting the compound metal layer 12a to the body region of the single crystal semiconductor layer 3, the pn junction disposed at the channel surface and the Schottky junction formed between the compound metal layer 12a and the single crystal semiconductor layer 3 can be connected in parallel with each other between the source and the body region.

Therefore, on the source side, holes accumulated in the body region can be pulled out through the Schottky junction formed between the compound metal layer 12a and the single crystal semiconductor layer 3, and the body potential can be suppressed from rising positively. As a consequence, injection of electrons from the source to the body region can be suppressed, such that a bipolar operation with the body region functioning as a base can be avoided, while suppressing an increase in the resistance on the drain side.

Moreover, by arranging the high concentration impurity diffusion layer 6 below the side wall spacer 10a, while holes accumulated in the body region can be pulled out through the compound metal layer, a source edge area where carriers travel can be composed of a pn junction. Accordingly, in a sub-threshold region, a drain current can be decided by carriers that thermally surpass the sum of a built-in potential of the pn junction and a channel surface potential (a potential barrier at the surface of the source edge region), such that a bipolar operation of a field effect transistor can be avoided, and a steep rising characteristic (good Swing value) can be achieved. Also, the high concentration impurity diffusion layer can be formed in a self-alignment manner with respect to the gate electrode, such that a barrier among the source, channel inversion layer and drain where carriers travel can be eliminated under a gate voltage that is greater than a threshold value at which a channel is formed.

As a result, on-resistance of the field effect transistor can be lowered, and a high on-current and a high on/off ratio can be realized, such that higher operation speeds and lower power consumption of ICs can be achieved. Also, lowering of the breakdown voltage between source and drain can be suppressed, and high-voltage operations at about several V-several tens V can be accommodated.

Furthermore, by disposing the compound metal layer 12a separated from the dielectric layer 2, the single crystal semiconductor layer 3 can be disposed under the compound metal layer 12a. Accordingly, variations in the Schottky barrier and specific resistance in the compound metal layer 12a can be reduced, and the heat-resisting property can be improved.

Moreover, by contacting the low concentration impurity diffusion layer 7 to the body region in the single crystal semiconductor layer 3 on the drain side, control of the impurity concentration on the drain side becomes possible, and the electric field concentration in the drain edge area of the body region can be alleviated, such that the drain breakdown voltage can be improved.

Also, by providing the lower concentration impurity diffusion layer 7, the intermediate concentration impurity diffusion layer 8 and the high concentration impurity diffusion layer 9 successively from the side of the gate electrode 5 to the drain side, the impurity concentration in the drain edge area of the body region can be lowered while an increase in the drain resistance can be suppressed, and concentration of the electric field at the drain edge area of the body region can be alleviated, such that the drain breakdown voltage can be improved.

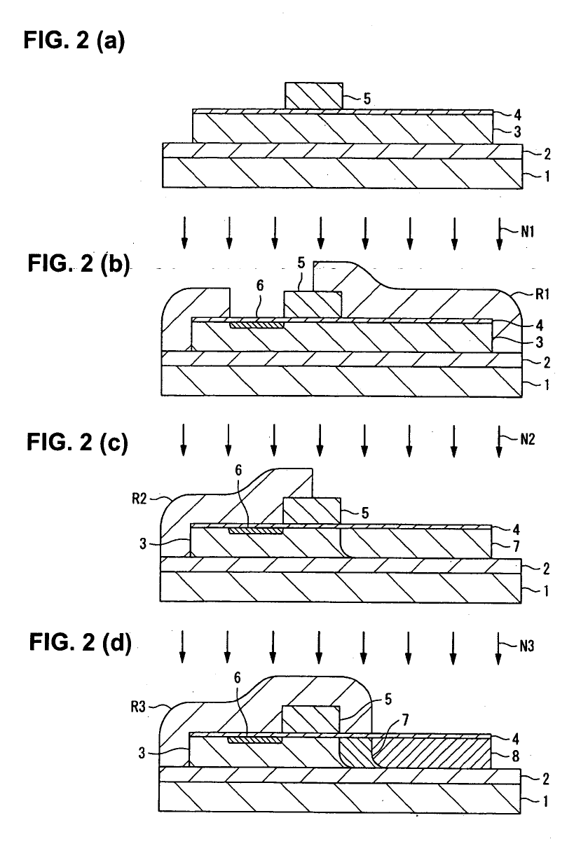

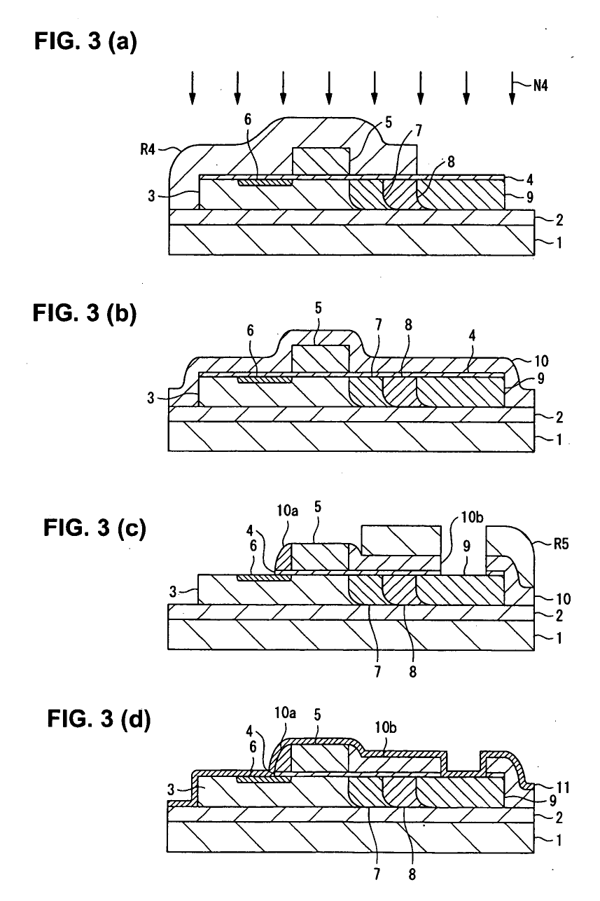

FIGS. 2 and 3 are cross-sectional views indicating a method for manufacturing a semiconductor device in accordance with an embodiment of the present invention.

In FIG. 2(a), a dielectric layer 2 is formed on a semiconductor substrate 1, and a single crystal semiconductor layer 3 is formed on the dielectric layer 2. Then, the single crystal semiconductor layer 3 is patterned by using of a photolithography technique and an etching technique, thereby conducting element isolation of the single crystal semiconductor layer 3. After impurities such as As, P, B or the like are ion-injected in the single crystal semiconductor layer 3, the single crystal semiconductor layer 3 is thermally oxidized, whereby a gate dielectric film 4 is formed on the single crystal silicon layer 3. Then, by using an appropriate method such as a CVD method, a polysilicon layer is formed on the single crystal semiconductor layer 3 where the gate dielectric layer 4 is formed. Then, by using of a photolithography technique and an etching technique, the polysilicon layer is patterned, thereby forming a gate electrode 5 on the gate dielectric film 4.

Next, as shown in FIG. 2(b), by using a photolithography technique, a resist pattern R1 that covers the drain side with respect to the gate electrode 5, and exposes the source side with respect to the gate electrode 5 is formed. It is noted that, when the drain side with respect to the gate electrode 5 is covered, it is desirable to form the resist pattern R1 so that a part of the resist pattern R1 may hang over the gate electrode 5. Then, by using the gate electrode 5 and the resist pattern R1 as a mask, an ion injection N1 of impurities such as As, P, B or the like is conducted on the single crystal silicon layer 3, thereby forming a high concentration impurity diffusion layer 6 having a depth shallower than the film thickness of the single crystal silicon layer 3 on the source side.

Next, as shown in FIG. 2(c), when the high concentration impurity diffusion layer 6 is formed in the single crystal semiconductor layer 3, the resist pattern R1 is removed from the single crystal semiconductor layer 3. Then, by using a photolithography technique, a resist pattern R2 that covers the source side with respect to the gate electrode 5, and exposes the drain side with respect to the gate electrode 5 is formed. It is noted that, when the source side with respect to the gate electrode 5 is covered, it is desirable to form the resist pattern R2 so that a part of the resist pattern R2 may hang over the gate electrode 5. Then, by using the gate electrode 5 and the resist pattern R2 as a mask, an ion injection N2 of impurities such as As, P, B or the like is conducted on the single crystal silicon layer 3, thereby forming a low concentration impurity diffusion layer 7 having a depth set to reach the dielectric layer 2 on the drain side.

Next, as shown in FIG. 2(d), when the low concentration impurity diffusion layer 7 is formed in the single crystal semiconductor layer 3, the resist pattern R2 is removed from the single crystal semiconductor layer 3. Then, by using a photolithography technique, a resist pattern R3 that covers the source side and the lower concentration impurity diffusion layer 7 closer to the gate electrode 5, and exposes the lower concentration impurity diffusion layer 7 closer to the drain side is formed. Then, by using the gate electrode 5 and the resist pattern R3 as a mask, an ion injection N3 of impurities such as As, P, B or the like is conducted on the single crystal silicon layer 3, thereby forming an intermediate concentration impurity diffusion layer 8 having a depth set to reach the dielectric layer 2 on the drain side.

Next, as shown in FIG. 3(a), when the intermediate concentration impurity diffusion layer 8 is formed in the single crystal semiconductor layer 3, the resist pattern R3 is removed from the single crystal semiconductor layer 3. Then, by using a photolithography technique, a resist pattern R4 that covers the source side and the intermediate concentration impurity diffusion layer 8 closer to the gate electrode 5, and exposes the intermediate concentration impurity diffusion layer 8 closer to the drain side is formed. Then, by using the gate electrode 5 and the resist pattern R4 as a mask, an ion injection N4 of impurities such as As, P, B or the like is conducted on the single crystal silicon layer 3, thereby forming a high concentration impurity diffusion layer 9 having a depth set to reach the dielectric layer 2 on the drain side.

Next, as shown in FIG. 3(b), when the high concentration impurity diffusion layer 8 is formed in the single crystal semiconductor layer 3, the resist pattern R4 is removed from the single crystal semiconductor layer 3. Then, by using a CVD method or the like, a dielectric layer 10 is formed over the dielectric film 2 and the entire surface of the single crystal silicon layer 3 where the high concentration impurity diffusion layer 9 is formed.

Then, as shown in FIG. 3(c), by using a photolithography technique, a resist pattern R5 that covers the lower concentration impurity diffusion layer 7 and the intermediate concentration impurity diffusion layer 8, and exposes the gate electrode 5, the high concentration impurity diffusion layer 6 on the source side, and a part of the dielectric layer 10 located above the high concentration impurity diffusion layer 9 on the drain side is formed. Then, by using the resist pattern R5 as a mask, an anisotropic etching such as RIE is conducted on the dielectric layer 10, thereby forming a side wall 10a on a side wall of the gate electrode 5 on the source side, and an opening section 10b in the dielectric layer 10 that exposes the high concentration impurity diffusion layer 9.

Next, as shown in FIG. 3(d), when the side wall 10a and the opening section 10b are formed on the single crystal semiconductor layer 3, the resist pattern R5 is removed from the single crystal semiconductor layer 3. Then, a metal film 11 is formed by a sputter method or the like over the single crystal semiconductor layer 3 where the side wall 10a and the opening section 10b are formed. As the metal film 11, one that forms an intermetallic compound upon reacting with the single crystal semiconductor layer 3, such as, for example, a Ti film, Co film, W film, Mo film, Ni film, Er film, Pt film, or the like can be used. For example, when the single crystal silicon layer 3 consists of Si, the metal film 11 can form silicide by reacting with the single crystal semiconductor layer 3.

Next, as shown in FIG. 1, the single crystal semiconductor layer 3 where the metal film 11 is formed is heat-treated to thereby react the metal film 11 and the single crystal silicon layer 3, whereby a compound metal layer 12a is formed on the source side, a compound metal layer 12b is formed inside the high concentration impurity diffusion layer 9, and a compound metal layer 12c is formed on the gate electrode 5. It is desirable that the bottom of the compound metal layer 12a does not come in contact with the dielectric layer 2, and the thickness of the compound metal layer 12a is greater than the depth of the high concentration impurity diffusion layer 6. Then, unreacted portions of the metal film 11 are removed by wet etching.

Accordingly, on the source side, the single crystal silicon layer 3 can be disposed below the compound metal layer 12a, and the high concentration impurity diffusion layer 6 and the compound metal layer 12a can be formed in a self-alignment manner, both of which are disposed in a manner to contact the body region. Further, on the drain side, an increase in the drain resistance can be suppressed, and the impurity concentration at the drain edge section of the body region can be lowered. Consequently, variations in the Schottky barrier and specific resistance of the compound metal layer 12a can be reduced, and holes accumulated in the body region can be pulled out through the compound metal layer 12a. Also, a barrier among the source, channel inversion layer and drain where carriers travel can be eliminated under a gate voltage that is larger than a threshold value at which a channel is formed, and concentration of the electric field at the drain edge section of the body region can be alleviated. As a result, a bipolar operation with the body region acting as a base can be avoided, while lowering of on-current can be suppressed, such that field effect transistors capable of achieving higher operation speeds and lower power consumption of ICs can be stably manufactured.

It is noted that, in the embodiment described above, a field effect transistor formed on a SOI substrate is explained as an example. However, the present invention is also applicable to devices other than field effect transistors formed on a SOI substrate, such as, for example, TFT (Thin Film Transistor) and the like.

Also, in the embodiment described above, to increase the impurity concentration in stages from the side of the gate electrode 5 toward the drain side, a method to provide the lower concentration impurity diffusion layer 7, the intermediate concentration impurity diffusion layer 8, and the high concentration impurity diffusion layer 9 in three stages is described. However, the number of stages of impurity concentration is not necessarily limited to three stages, and one stage, two stages, four stages or more are also acceptable. The impurity concentration on the drain side may be successively changed.

1. A semiconductor device comprising:
a semiconductor layer formed on a dielectric;
a gate electrode formed on the semiconductor layer;
a compound metal layer disposed on a source side to contact a body region of the semiconductor layer; and
an impurity diffusion layer disposed on a drain side to contact the body region of the semiconductor layer.

2. A semiconductor device according to claim 1, further comprising:
a side wall formed on a source side with respect to the gate electrode; and
a high concentration impurity diffusion layer that is disposed to contact the body region of the semiconductor layer and the compound metal layer under the side wall.

3. A semiconductor device according to claim 1, wherein the compound metal layer is separated from the dielectric, and the high concentration impurity diffusion layer has a depth that is shallower than a thickness of the compound metal layer.

4. A semiconductor device comprising:
a semiconductor layer formed on a dielectric;
a gate electrode formed on the semiconductor layer;
a side wall formed on a source side with respect to the gate electrode;
a first intermetallic compound layer disposed on a source side to contact a body region of the semiconductor layer and separated from the gate electrode by a width of the side wall;
a first impurity diffusion layer that is formed in the semiconductor layer under the side wall and shallower than a thickness of the first intermetallic compound layer;
a second impurity diffusion layer disposed on the drain side to contact the body region of the semiconductor layer and the dielectric; and
a second intermetallic compound layer formed inside the second impurity diffusion layer.

5. A semiconductor device according to claim 4, wherein the first intermetallic compound layer and the second intermetallic compound layer are separated from the dielectric.

6. A semiconductor device according to claim 4, wherein the second impurity diffusion layer has a plurality of regions with impurity concentrations gradually increasing from the gate electrode side to the drain side.

7. A method for manufacturing a semiconductor device, comprising the steps of:
forming a gate dielectric film on a semiconductor layer formed on a dielectric;
forming a gate electrode on the gate dielectric film;
forming a first resist pattern that covers the semiconductor layer on a drain side with respect to the gate electrode and exposes the semiconductor layer on a source side;
forming a high concentration impurity diffusion layer having a depth shallower than a film thickness of the semiconductor layer on the source side by conducting an ion injection using the gate electrode and the first resist pattern as a mask;
forming a second resist pattern that covers the semiconductor layer on the source side with respect to the gate electrode, and exposes the semiconductor layer on the drain side;
forming an impurity diffusion layer having a depth that is set to reach the dielectric on the drain side by conducting an ion injection using the gate electrode and the second resist pattern as a mask;
depositing a dielectric film on the semiconductor layer having the impurity diffusion layer formed thereon;
conducting an anisotropic etching of the dielectric film to expose a part of the high concentration impurity diffusion layer and form a side wall disposed on the source side with respect to the gate electrode;
forming a metal layer on the semiconductor layer where the part of the high concentration impurity diffusion layer is exposed;
reacting the metal layer and the semiconductor layer to form a compound metal layer on the source side, having a film thickness greater than a depth of the high concentration impurity diffusion layer and separated from the dielectric; and
removing an unreacted portion of the metal layer.

8. A method for manufacturing a semiconductor device, comprising the steps of:
forming a gate dielectric film on a semiconductor layer formed on a dielectric;
forming a gate electrode on the gate dielectric film;
forming a first resist pattern that covers the semiconductor layer on a drain side with respect to the gate electrode and exposes the semiconductor layer on a source side;
forming a high concentration impurity diffusion layer having a depth shallower than a film thickness of the semiconductor layer on the source side by conducting an ion injection using the gate electrode and the first resist pattern as a mask;
forming a second resist pattern that covers the semiconductor layer on the source side with respect to the gate electrode, and exposes the semiconductor layer on the drain side;
forming a first impurity diffusion layer having a depth that is set to reach the dielectric on the drain side by conducting an ion injection using the gate electrode and the second resist pattern as a mask;
forming a third resist pattern that covers the semiconductor layer on the source side with respect to the gate electrode, and exposes an area among the first impurity diffusion layer close to the drain;
forming a second impurity diffusion layer having an impurity concentration higher than the first impurity diffusion layer and closer to the drain than the first impurity diffusion layer by conducting an ion injection using the gate electrode and the third resist pattern as a mask;
depositing a dielectric film on the semiconductor layer having the second impurity diffusion layer formed thereon;
forming a fourth resist pattern on the dielectric film disposed to expose the source side with respect to the gate electrode, and cover the first impurity diffusion layer;
conducting an anisotropic etching of the dielectric film using the fourth resist pattern as a mask, to form a side wall that is disposed on the source side with respect to the gate electrode and exposes a part of the high concentration impurity diffusion layer, and to form an opening section in the dielectric film which is disposed on the drain side with respect to the gate electrode and exposes the second impurity diffusion layer;
forming a metal layer on the semiconductor layer where the part of the high concentration impurity diffusion layer and the second impurity diffusion layer are exposed;
reacting the metal layer and the semiconductor layer to form a first intermetallic compound layer on the source side, having a film thickness greater than a depth of the high concentration impurity diffusion layer and separated from the dielectric, and a second intermetallic compound layer on the drain side disposed inside the second impurity diffusion layer; and
removing an unreacted portion of the metal layer.
